(19) United States
(12) Patent Application Publication
(10) Pub. No.: US 2012/0028011 A1
(43) Pub. Date: Feb. 2, 2012

(54) SELF-PASSIVATING MECHANICALLY STABLE HERMETIC THIN FILM

(76) Inventors: CHONG Pyung An, Painted Post, NY (US); Mark Alejandro Quesada, Horseheads, NY (US)

(21) Appl. No.: 12/879,578

(22) Filed: Sep. 10, 2010

Related U.S. Application Data
(60) Provisional application No. 61/368,011, filed on Jul. 27, 2010.

(51) Int. Cl. B32B 7/02; B29C 35/08; C23C 14/34; B05D 3/04

(52) U.S. Cl. 428/213; 428/212; 427/343; 264/400; 204/192.15

(57) ABSTRACT

A hermetic thin film includes a first inorganic layer and a second inorganic layer contiguous with the first inorganic layer, wherein the second inorganic layer is formed as a reaction product of the first inorganic layer with oxygen and has a molar volume that is about −1% to 15% greater than a molar volume of the first inorganic layer. An equilibrium thickness of the second inorganic layer is at least 10% of but less than an as-deposited thickness of the first inorganic layer.

This application claims the benefit of U.S. Provisional Application No. 61/368,011, filed Jul. 27, 2010, which is incorporated by reference herein in its entirety.

### BACKGROUND AND SUMMARY

The present disclosure relates generally to hermetic barrier layers, and more particularly to self-passivating, inorganic, mechanically stable hermetic thin films.

Recent research has shown that single-layer thin film inorganic oxides, at or near room temperature, typically contain nanoscale porosity, pinholes and/or defects that preclude or challenge their successful use as hermetic barrier layers. In order to address the apparent deficiencies associated with single-layer films, multi-layer encapsulation schemes have been adopted. The use of multiple layers can minimize or alleviate defect-enabled diffusion and substantially inhibit ambient moisture and oxygen permeation. Multiple layer approaches generally involve alternating inorganic and polymer layers, where an inorganic layer is typically formed both immediately adjacent the substrate or workpiece to be protected and as the terminal or topmost layer in the multi-layer stack. Because multiple layer approaches are generally complex and costly, economical thin film hermetic layers and methods for forming them are highly desirable.

Hermetic barrier layers formed according to the present disclosure comprise a single deposited inorganic layer that during and/or after its formation reacts with inward diffusing moisture or oxygen to form a self-passivating, mechanically stable hermetic thin film. The reaction product between moisture or oxygen and the first inorganic layer forms a second inorganic layer at the deposited layer-ambient interface. The first and second inorganic layers cooperate to isolate and protect an underlying substrate or workpiece.

In embodiments, the first inorganic layer can be formed on a surface of a workpiece by room temperature sputtering from a suitable target material. As deposited, the first inorganic layer can be substantially amorphous. The workpiece can be, for example, an organic electronic device such as an organic light emitting diode. Reactivity of the first inorganic layer with moisture or oxygen is sufficiently compressive and cooperative that a self-sealing structure is formed having mechanical integrity substantially devoid of film buckling, delamination or spalling.

According to one embodiment, a hermetic thin film comprises a first inorganic layer formed over a substrate, and a second inorganic layer contiguous with the first inorganic layer. The first inorganic layer and the second inorganic layer comprise substantially equivalent elemental constituents, while a molar volume of the second inorganic layer is from about −1% to 15% greater than a molar volume of the first inorganic layer. An equilibrium thickness of the second inorganic layer, which is formed via oxidation of the first inorganic layer, is at least 10% of, but less than, an initial thickness of the first inorganic layer. The second inorganic layer according to embodiments has a crystalline microstructure.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention and together with the description serve to explain the principles and operations of the invention.

### BRIEF DESCRIPTION OF THE DRAWINGS

FIG. 1 is a schematic diagram of a single chamber sputter tool for forming self-passivating, mechanically stable hermetic thin films;

FIG. 2 is an illustration of a calcium-patch test sample for accelerated evaluation of hermeticity;

FIG. 3 shows test results for non-hermetically sealed (left) and hermetically sealed (right) calcium patches following accelerated testing;

FIG. 4 shows glancing angle (A, C) and thin film (B, D) x-ray diffraction (XRD) spectra for a hermetic film-forming material (top series) and a non-hermetic film forming material (bottom series);

FIG. 5 is a series of glancing angle XRD spectra for hermetic (top) and non-hermetic (bottom) films following accelerated testing; and

FIGS. 6A-6I show a series of glancing angle XRD spectra for hermetic thin films following accelerated testing.

### DETAILED DESCRIPTION

A method of forming a self-passivating, mechanically stable hermetic thin film comprises forming a first inorganic layer over a substrate, and exposing a free-surface of the first inorganic layer to oxygen to form a second inorganic layer contiguous with the first inorganic layer, wherein a molar volume of the second inorganic layer is from about −1% to 15% greater than a molar volume of the first inorganic layer, and an equilibrium thickness of the second inorganic layer is at least 10% of but less than an initial thickness of the first inorganic layer. The first inorganic layer can be amorphous, while the second inorganic layer can be at least partially crystalline.

In embodiments, the molar volume change (e.g., increase) manifests as a compressive force within the layers that contributes to a self-sealing phenomenon. Because the second inorganic layer is formed as the spontaneous reaction product of the first inorganic layer with oxygen, as-deposited layers (first inorganic layers) that successfully form hermetic films are less thermodynamically stable than the corresponding second inorganic layers. Thermodynamically stability is reflected in the respective Gibbs free energies of formation.

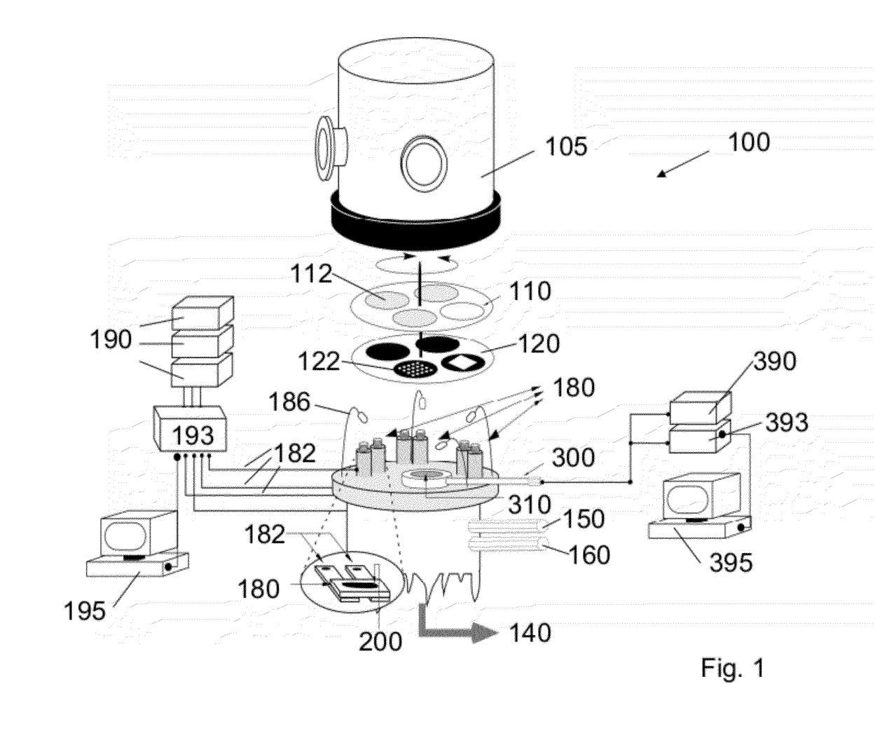

Self-passivating, mechanically stable hermetic thin films can be formed by physical vapor deposition (e.g., sputter deposition or laser ablation) or thermal evaporation of a suitable starting material onto a workpiece or test piece. A single-chamber sputter deposition apparatus 100 for forming such thin films is illustrated schematically in FIG. 1.

The apparatus 100 includes a vacuum chamber 105 having a substrate stage 110 onto which one or more substrates 112 can be mounted, and a mask stage 120, which can be used to mount shadow masks 122 for patterned deposition of different layers onto the substrates. The chamber 105 is equipped with a vacuum port 140 for controlling the interior pressure, as well as a water cooling port 150 and a gas inlet port 160. The vacuum chamber can be cryo-pumped (CTI-8200/Helix; MA, USA) and is capable of operating at pressures suitable for both evaporation processes (˜10⁻⁶ Torr) and RF sputter deposition processes (˜10⁻³ Torr).

As shown in FIG. 1, multiple evaporation fixtures 180, each having an optional corresponding shadow mask 122 for evaporating material onto a substrate 112 are connected via conductive leads 182 to a respective power supply 190. A starting material 200 to be evaporated can be placed into each fixture 180. Thickness monitors 186 can be integrated into a feedback control loop including a controller 193 and a control station 195 in order to affect control of the amount of material deposited.

In an example system, each of the evaporation fixtures 180 are outfitted with a pair of copper leads 182 to provide DC current at an operational power of about 80-180 Watts. The effective fixture resistance will generally be a function of its geometry, which will determine the precise current and wattage.

An RF sputter gun 300 having a sputter target 310 is also provided for forming a layer of inorganic oxide on a substrate. The RF sputter gun 300 is connected to a control station 395 via an RF power supply 390 and feedback controller 393. For sputtering inorganic, mechanically stable hermetic thin films, a water-cooled cylindrical RF sputtering gun (Onyx-3™, Angstrom Sciences, Pa) can be positioned within the chamber 105. Suitable RF deposition conditions include 50-150 W forward power (<1 W reflected power), which corresponds to a typical deposition rate of about ˜5 Å/second (Advanced Energy, Co, USA). In embodiments, an initial thickness (i.e., as-deposited thickness) of the first inorganic layer is less than 50 microns (e.g., about 45, 40, 35, 30, 25, 20, 15 or 10 microns). Formation of the second inorganic layer can occur when the first inorganic layer is exposed to oxygen, which can be in the form of ambient air, a water bath, or steam.

To evaluate the hermeticity of the hermetic barrier layers, calcium patch test samples were prepared using the single-chamber sputter deposition apparatus 100. In a first step, calcium shot (Stock #10127; Alfa Aesar) was evaporated through a shadow mask 122 to form 25 calcium dots (0.25 inch diameter, 100 nm thick) distributed in a 5×5 array on a 2.5 inch square glass substrate. For calcium evaporation, the chamber pressure was reduced to about 10⁻⁶ Torr. During an initial pre-soak step, power to the evaporation fixtures 180 was controlled at about 20 W for approximately 10 minutes, followed by a deposition step where the power was increased to 80-125 W to deposit about 100 nm thick calcium patterns on each substrate.

Following evaporation of the calcium, the patterned calcium patches were encapsulated using comparative inorganic oxide materials as well as hermetic inorganic oxide materials according to various embodiments. The inorganic oxide materials were deposited using room temperature RF sputtering of pressed powder sputter targets. The pressed powder targets were prepared separately using a manual heated bench-top hydraulic press (Carver Press, Model 4386, Wabash, Ind., USA). The press was typically operated at 20,000 psi for 2 hours and 200° C.

The RF power supply 390 and feedback control 393 (Advanced Energy, Co, USA) were used to form first inorganic oxide layers over the calcium having a thickness of about 2 micrometers. No post-deposition heat treatment was used. Chamber pressure during RF sputtering was about 1 milliTorr. The formation of a second inorganic layer over the first inorganic layer was initiated by ambient exposure of the test samples to room temperature and atmospheric pressure prior to testing.

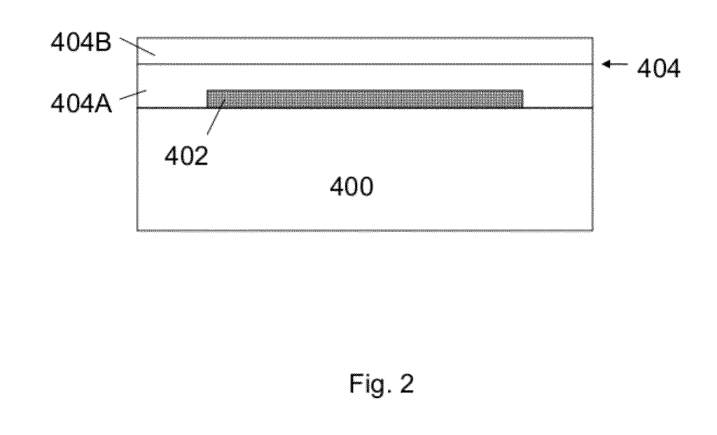

FIG. 2 is a cross-sectional view of a test sample comprising a glass substrate 400, a patterned calcium patch (˜100 nm) 402, and an inorganic oxide film (˜2 μm) 404. Following ambient exposure, the inorganic oxide film 404 comprises a first inorganic layer 404A and a second inorganic layer 404B. In order to evaluate the hermeticity of the inorganic oxide film, calcium patch test samples were placed into an oven and subjected to accelerated environmental aging at a fixed temperature and humidity, typically 85° C. and 85% relative humidity (“85/85 testing”).

The hermeticity test optically monitors the appearance of the vacuum-deposited calcium layers. As-deposited, each calcium patch has a highly reflective metallic appearance. Upon exposure to water and/or oxygen, the calcium reacts and the reaction product is opaque, white and flaky. Survival of the calcium patch in the 85/85 oven over 1000 hours is equivalent to the encapsulated film surviving 5-10 years of ambient operation. The detection limit of the test is approximately 10⁻⁷ g/m² per day at 60° C. and 90% relative humidity.

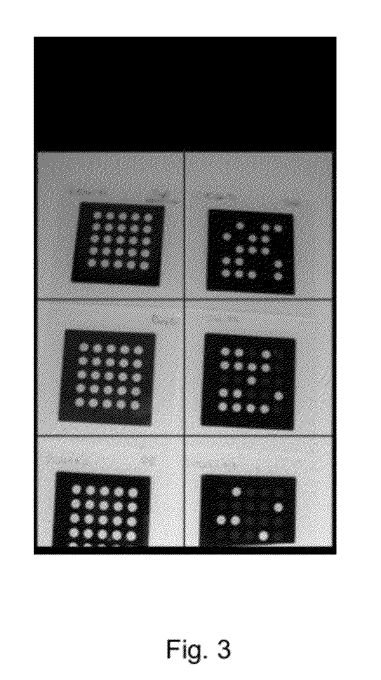

FIG. 3 illustrates behavior typical of non-hermetically sealed and hermetically sealed calcium patches after exposure to the 85/85 accelerated aging test. In FIG. 3, the left column shows non-hermetic encapsulation behavior for Cu₂O films formed directly over the patches. All of the Cu₂O-coated samples failed the accelerated testing, with catastrophic delamination of the calcium dot patches evidencing moisture penetration through the Cu₂O layer. The right column shows positive test results for nearly 50% of the samples comprising a CuO-deposited hermetic layer. In the right column of samples, the metallic finish of 34 intact calcium dots (out of 75 test samples) is evident.

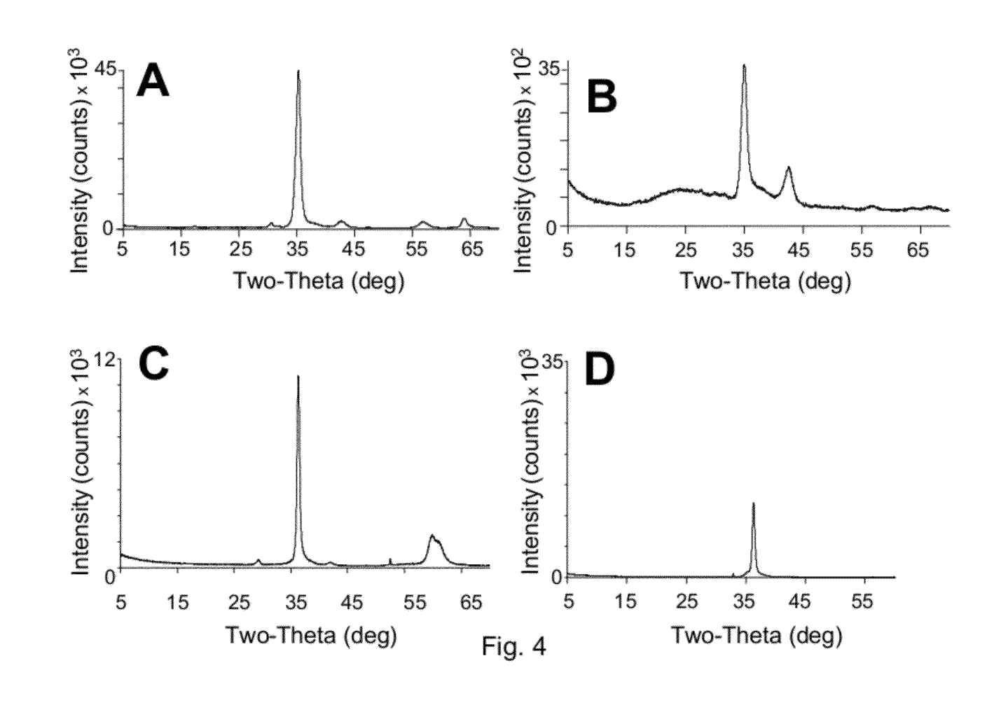

Both glancing angle x-ray diffraction (GIXRD) and traditional powder x-ray diffraction were used to evaluate the near surface and entire oxide layer, respectively, for both non-hermetic and hermetic deposited layers. FIG. 4 shows GIXRD data (plots A and C) and traditional powder reflections (plots B and D) for both hermetic CuO-deposited layers (plots A and B) and non-hermetic Cu₂O-deposited layers (plots C and D). Typically, the 1 degree glancing angle used to generate the GIXRD scans of FIGS. 4A and 4C probes a near-surface depth of approximately 50-300 nanometers.

Referring still to FIG. 4, the hermetic CuO-deposited film (plot A) exhibits near surface reflections that index to the phase paramelaconite (Cu₄O₃), though the interior of the deposited film (plot B) exhibits reflections consistent with a significant amorphous copper oxide content. The paramelaconite layer corresponds to the second inorganic layer, which formed via oxidation of the first inorganic layer (CuO) that was formed directly over the calcium patches. In contrast, the non-hermetic Cu₂O-deposted layer exhibits x-ray reflections in both scans consistent with Cu₂O.

The XRD results suggests that hermetic films exhibit a significant and cooperative reaction of the sputtered (as-deposited) material with moisture in the near surface region only, while non-hermetic films react with moisture in their entirety yielding significant diffusion channels which preclude effective hermeticity. For the copper oxide system, the hermetic film data (deposited CuO) suggest that paramelaconite crystallite layer forms atop an amorphous base of un-reacted sputtered CuO, thus forming a mechanically stable and hermetic composite layer.

In embodiments of the present disclosure, a hermetic thin film is formed by first depositing a first inorganic layer on a workpiece. The first inorganic layer is exposed to moisture and/or oxygen to oxidize a near surface region of the first inorganic layer to form a second inorganic layer. The resulting hermetic thin film is thus a composite of the as-deposited first inorganic layer and a second inorganic layer, which forms contiguous with the first as the reaction product of the first layer with moisture and/or oxygen.

A survey of several binary oxide systems reveals other materials capable of forming self-passivating hermetic thin films In the tin oxide system, for example, as-deposited amorphous SnO reacts with moisture/oxygen to form crystalline SnO₂ and the resulting composite layer exhibits good hermeticity. When SnO₂ is deposited as the first inorganic layer, however, the resulting film is not hermetic.

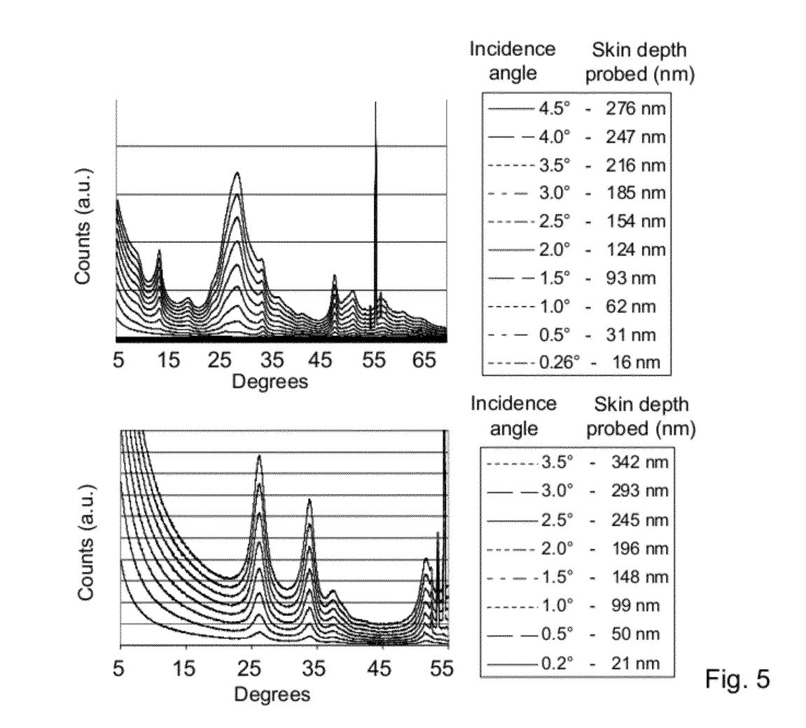

As seen with reference to FIG. 5, which shows GIXRD spectra for SnO (top) and SnO₂-deposited films (bottom) after 85/85 exposure, the hermetic film (top) exhibits a crystalline SnO₂ (passivation) layer that has formed over the deposited amorphous SnO layer, while the non-hermetic film exhibits a pure crystalline morphology.

According to further embodiments, the choice of the hermetic thin film material(s) and the processing conditions for incorporating the hermetic thin film materials are sufficiently flexible that the workpiece is not adversely affected by formation of the hermetic thin film Exemplary hermetic thin film materials can include copper oxide, tin oxide, silicon oxide, tin phosphate, tin fluorophosphate, chalcogenide glass, tellurite glass, borate glass, as well as combinations thereof. Optionally, the hermetic thin film can include one or more dopants, including but not limited to tungsten and niobium.

A composition of a doped tin fluorophosphate starting material suitable for forming a first inorganic comprises 35 to 50 mole percent SnO, 30 to 40 mole percent SnF₂, 15 to 25 mole percent P₂O₅, and 1.5 to 3 mole percent of a dopant oxide such as WO₃ and/or Nb₂O₅.

In embodiments, the thin film can be derived from room temperature sputtering of one or more of the foregoing materials or precursors for these materials, though other thin film deposition techniques can be used. In order to accommodate various workpiece architectures, deposition masks can be used to produce a suitably patterned hermetic thin film. Alternatively, conventional lithography and etching techniques can be used to form a patterned hermetic thin film from a uniform layer.

Additional aspects of suitable hermetic thin film materials are disclosed in commonly-owned U.S. Application No. 61/130,506 and U.S. Patent Application Publication Nos. 2007/0252526 and 2007/0040501, the entire contents of which are hereby incorporated herein by reference in their entirety.

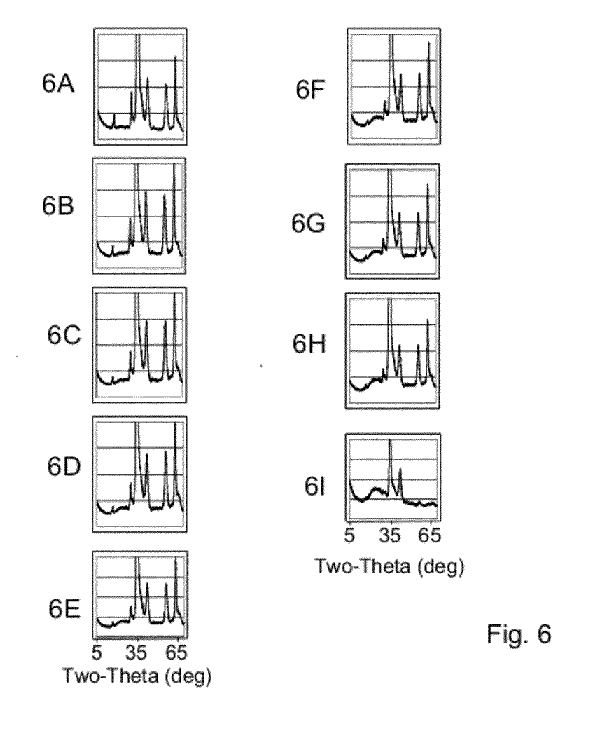

FIGS. 6A-6H show a series of GIXRD plots, and FIG. 61 shows a Bragg XRD spectrum for a CuO-deposited hermetic thin film following accelerated testing. Bragg diffraction from the entire film volume has an amorphous character, with the paramelaconite phase present at/near the film's surface. Using a CuO density of 6.31 g/cm³, a mass attenuation coefficient of 44.65 cm²/g, and an attenuation coefficient of 281.761 cm⁻¹, the paramelaconite depth was estimated from the GIXRD plots of FIG. 6. In FIGS. 6A-6H, successive glancing incident x-ray diffraction spectra obtained at respective incident angles of 1°, 1.5°, 2°, 2.5°, 3.0°, 3.5°, 4°, and 4.5° show the oxidized surface (paramelaconite) comprises between 31% (619 nm) and 46% (929 nm) of the original 2 microns of sputtered CuO after exposure to 85° C. and 85% relative humidity for 1092 hours. A summary of the calculated surface depth (probed depth) for each GIXRD angle is shown in Table 1.

In embodiments, an equilibrium thickness of the second inorganic layer is at least 10% (e.g., at least 10, 15, 20, 25, 30, 35, 40, 45, 50, 55, 60, 65 or 75%) of the initial thickness of the first inorganic layer.

TABLE 1
Paramelaconite depth profile

| FIG. | GIXRD angle (degrees) | Probed Depth (nm) |
|---|---|---|
| 6A | 1 | 300 |
| 6B | 1.5 | 465 |
| 6C | 2 | 619 |
| 6D | 2.5 | 774 |
| 6E | 3 | 929 |
| 6F | 3.5 | 1083 |
| 6G | 4 | 1238 |
| 6H | 4.5 | 1392 |
| 6I | n/a | 2000 |

Table 2 highlights the impact of volume change about the central metal ion on the contribution to film stress of the surface hydration products. It has been discovered that a narrow band corresponding to an approximate 15% or less increase in the molar volume change contributes to a hermetically-effective compressive force. In embodiments, a molar volume of the second inorganic layer is from about −1% to 15% (i.e., −1, 0, 1, 2, 3, 4, 5, 6, 7, 8, 9, 10, 11, 12, 13, 14 or 15%) greater than a molar volume of the first inorganic layer. The resulting self-sealing behavior (i.e., hermeticity) appears related to the volume expansion.

TABLE 2
Calculated Molar Volume Change for Various Materials

| Sputter Target | | Δ Molar | |
|---|---|---|---|
| Material/First | | Volume | Hermetic |
| Inorganic Layer | Second Inorganic Layer | [%] | Layer? |
| SnO | SnO₂ | 5.34 | yes |
| FeO | Fe₂O₃^{†} | 27.01 | no |
| Sb₂O₃ | Sb₂O₅^{†} | 63.10 | no |
| (senarmonitite) | | | |
| Sb₂O₃ | Sb₂O₅^{†} | 67.05 | no |
| (valentinite) | | | |
| Sb₂O₃ | Sb + 3Sb + 5O₄ (cervantite) | −9.61 | no |
| (valentinite) | | | |
| Sb₂O₃ | Sb₃O₆(OH) (stibiconite)^{†} | −14.80 | no |
| (valentinite) | | | |
| TiO₃ | TiO₂^{†} | 17.76 | no |
| SiO | SiO₂ (β-quartz)^{†} | 12.21 | yes |
| SiO | SiO₂ (vitreous)^{†} | 35.30 | no |
| Cu₂O | Cu⁺₂Cu²⁺₂O₃(paramelaconite)^{†} | 12.30 | no |
| CuO | Cu⁺₂Cu²⁺₂O₃ (paramelaconite) | 0.97 | yes |

^{†}estimate

Table 3 shows the hermetic-film-forming inorganic oxide was always the least thermodynamically stable oxide, as reflected in its Gibbs free energy of formation, for a given elemental pair. This suggests that as-deposited inorganic oxide films are metastable and thus reactive towards hydrolysis and/or oxidation.

TABLE 3
Gibbs Formation Free Energy (ΔG°_{formation}) of Various Oxides

| Target Material | ΔG°_{formation} [kJ/mol] | Hermetic Layer |
|---|---|---|
| SnO | −251.9 | yes |
| Sn₂O | −515.8 | no |
| SiO | −405.5 | yes |
| SiO₂ | −850.9 | no |
| CuO | −129.7 | yes |
| Cu₂O | −146.0 | no |

A hermetic layer is a layer which, for practical purposes, is considered substantially airtight and substantially impervious to moisture. By way of example, the hermetic thin film can be configured to limit the transpiration (diffusion) of oxygen to less than about 10⁻² cm³/m²/day (e.g., less than about 10⁻³ cm³/m²/day), and limit the transpiration (diffusion) of water to about 10⁻² g/m²/day (e.g., less than about 10⁻³, 10⁴, 10⁻⁵ or 10⁻⁶ g/m²/day). In embodiments, the hermetic thin film substantially inhibits air and water from contacting an underlying workpiece.

As used herein, the singular forms “a,” “an” and “the” include plural referents unless the context clearly dictates otherwise. Thus, for example, reference to a “layer” includes examples having two or more such “layers” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It is also noted that recitations herein refer to a component of the present invention being “configured” or “adapted to” function in a particular way. In this respect, such a component is “configured” or “adapted to” embody a particular property, or function in a particular manner, where such recitations are structural recitations as opposed to recitations of intended use. More specifically, the references herein to the manner in which a component is “configured” or “adapted to” denotes an existing physical condition of the component and, as such, is to be taken as a definite recitation of the structural characteristics of the component.

It will be apparent to those skilled in the art that various modifications and variations can be made to the present invention without departing from the spirit and scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A hermetic thin film, comprising:
a first inorganic layer having an initial thickness formed over a substrate; and
a second inorganic layer contiguous with the first inorganic layer; wherein the first inorganic layer and the second inorganic layer comprise substantially equivalent elemental constituents;
a molar volume of the second inorganic layer is from about −1% to 15% greater than a molar volume of the first inorganic layer; and
an equilibrium thickness of the second inorganic layer is at least 10% of but less than the initial thickness of the first inorganic layer.

2. The hermetic thin film according to claim 1, wherein the first inorganic layer is amorphous.

3. The hermetic thin film according to claim 1, wherein the second inorganic layer is crystalline.

4. The hermetic thin film according to claim 1, wherein the first inorganic layer comprises a first oxide of copper and the second inorganic layer comprises a second oxide of copper.

5. The hermetic thin film according to claim 1, wherein the first inorganic layer comprises an oxide of copper and the second inorganic layer comprises Cu₄O₃.

6. The hermetic thin film according to claim 5, wherein the oxide of copper is CuO.

7. The hermetic thin film according to claim 1, wherein the first inorganic layer comprises a doped tin fluorophosphate glass.

8. The hermetic thin film according to claim 7, wherein a composition of the doped tin fluorophosphate glass comprises 35 to 50 mole percent SnO, 30 to 40 mole percent SnF₂, 15 to 25 mole percent P₂O₅, and 1.5 to 3 mole percent of a dopant oxide selected from the group consisting of WO₃ and Nb₂O₅.

9. The hermetic thin film according to claim 1, wherein the second inorganic layer is substantially impervious to diffusion of air, oxygen, and water.

10. The hermetic thin film according to claim 1, wherein the second inorganic layer comprises a reaction product of the first inorganic layer and oxygen.

11. The hermetic thin film according to claim 1, wherein the initial thickness of the first inorganic layer is less than 50 microns.

12. A device at least partially sealed by the hermetic thin film according to claim 1.

13. A hermetic thin film, comprising:
a first inorganic layer having an initial thickness formed over a substrate; and
a second inorganic layer contiguous with the first inorganic layer; wherein
the first inorganic layer and the second inorganic layer comprise substantially equivalent elemental constituents;
a molar volume of the second inorganic layer is from about −1% to 15% greater than a molar volume of the first inorganic layer; and
the first inorganic layer comprises a first oxide of copper and the second inorganic layer comprises a second oxide of copper.

14. A method of forming a hermetic thin film, comprising:
forming a first inorganic layer over a substrate from a starting material, said first inorganic layer having an initial thickness; and
exposing a surface of the first inorganic layer to oxygen to form a second inorganic layer contiguous with the first inorganic layer, wherein
a molar volume of the second inorganic layer is from about −1% to 15% greater than a molar volume of the first inorganic layer; and
an equilibrium thickness of the second inorganic layer is at least 10% of but less than the initial thickness of the first inorganic layer.

15. The method according to claim 14, wherein the first inorganic layer is amorphous.

16. The method according to claim 14, wherein the second inorganic layer is crystalline.

17. The method according to claim 14, wherein the exposing to oxygen comprises exposing the first inorganic layer to at least one of elemental oxygen, molecular oxygen or compounds comprising oxygen.

18. The method according to claim 14, wherein the exposing to oxygen comprises exposing the first inorganic layer to at least one of air or water.

19. The method according to claim 14, wherein the exposing to oxygen comprises dipping the first inorganic layer into a water bath or exposing the first inorganic layer to steam.

20. The method according to claim 14, wherein the exposing to oxygen and formation of the second inorganic layer occur at about room temperature and atmospheric pressure.

21. The method according to claim 14, wherein the first inorganic layer comprises a first oxide of copper and the second inorganic layer comprises a second oxide of copper.

22. The method according to claim 14, wherein the first inorganic layer comprises an oxide of copper and the second inorganic layer comprises Cu₄O₃.

23. The method according to claim 22, wherein the oxide of copper is CuO.

24. The method according to claim 14, wherein the first inorganic layer comprises a doped tin fluorophosphate glass.

25. The method according to claim 24, wherein a composition of the doped tin fluorophosphate glass comprises 35 to 50 mole percent SnO, 30 to 40 mole percent SnF₂, 15 to 25 mole percent P₂O₅, and 1.5 to 3 mole percent of a dopant oxide selected from the group consisting of WO₃ and Nb₂O₅.

26. The method according to claim 14, wherein the initial thickness of the first inorganic layer is less than 50 microns.

27. The method according to claim 14, wherein a method of forming the inorganic layer is selected from the group consisting of sputtering, laser ablation and thermal evaporation.

28. The method according to claim 14, wherein a composition of the starting material is substantially identical to a composition of the first inorganic layer.

29. The method according to claim 14, wherein the starting material is solid, liquid or gaseous.

30. The method according to claim 14, wherein the starting material is crystalline or amorphous.

31. The method according to claim 14, wherein the second inorganic layer comprises a reaction product of the first inorganic layer and oxygen.
